(19) United States
(12) Patent Application Publication
(10) Pub. No.: US 2026/0165094 A1
(43) Pub. Date: Jun. 11, 2026

(54) METHOD FOR MANUFACTURING SEMICONDUCTOR DEVICE USING AN AREA SELECTIVE DEPOSITION PROCESS

(71) Applicant: Samsung Electronics Co., Ltd., Suwon-si (KR)

(72) Inventors: Sang Hoon AHN, Suwon-si (KR); Dong Hyung KIM, Suwon-si (KR); Ah Hyun LEE, Suwon-si (KR); Jang-Hee LEE, Suwon-si (KR); Yong Soon CHOI, Suwon-si (KR); Jae Wook HA, Suwon-si (KR); Yong Kwan KIM, Suwon-si (KR); Hui-Jung KIM, Suwon-si (KR)

(21) Appl. No.: 19/396,476

(22) Filed: Nov. 21, 2025

(30) Foreign Application Priority Data
Dec. 6, 2024 (KR) 10-2024-0180542

(51) Int. Cl. H01L 21/033; H01L 21/308; H01L 21/311; H01L 21/3213

(52) U.S. Cl. CPC H10P 76/4085; H10P 50/692; H10P 50/695; H10P 50/71; H10P 50/73; H10P 76/405

(57) ABSTRACT

A method for manufacturing a semiconductor device includes forming sacrificial mask patterns on an etching target layer, forming a hard mask pattern between the sacrificial mask patterns; removing the sacrificial mask patterns, wherein an inhibition ratio, indicating a degree to which formation of the hard mask pattern is suppressed on the sidewall of the sacrificial mask patterns, increases as the sidewall extends away from the etching target layer.

### CROSS-REFERENCE TO RELATED APPLICATION

This application claims priority under 35 U.S.C. 119 to Korean Patent Application No. 10-2024-0180542 filed on Dec. 6, 2024 in the Korean Intellectual Property Office, the disclosure of which is incorporated herein by reference in its entirety.

### BACKGROUND

### 1. Technical Field

The present disclosure relates to a method for manufacturing a semiconductor device.

### 2. Description of Related Art

As minimum feature sizes of semiconductor devices are scaled down and more densely integrated, advanced multi-layer stacking techniques for stacking circuits upwardly and forming high aspect ratio structures with nanoscale ultra-fine patterns are increasingly used.

However, there are technical limitations in accurately forming ultra-fine patterns having a high aspect ratio by conventional photoresist-based lithography methods. To overcome this problem, a hard mask having a higher etch selectivity than that of a photoresist mask, along with a process for etching the hard mask, may be used.

### SUMMARY

A technical purpose of the present disclosure is to provide a method for manufacturing a semiconductor device in which a hard mask pattern is formed without a process of etching a hard mask, and the semiconductor device is manufactured using the formed hard mask pattern.

The technical purposes of the present disclosure are not limited to the technical purposes mentioned above, and other technical purposes as not mentioned may be clearly understood by those skilled in the art from descriptions as set forth below.

According to an aspect of the disclosure, there is provided a method for manufacturing a semiconductor device that includes forming a sacrificial mask layer on an etching target layer, patterning the sacrificial mask layer to form sacrificial mask patterns, forming a hard mask pattern by selectively depositing hard mask material between the sacrificial mask patterns, and removing the sacrificial mask patterns, wherein an inhibition ratio, indicating a degree to which formation of the hard mask pattern is suppressed on the sidewall of the sacrificial mask patterns, increases as the sidewall extends upward, away from the etching target layer.

According to an aspect of the disclosure, there is provided a method for manufacturing a semiconductor device that includes forming a sacrificial mask layer on an etching target layer, patterning the sacrificial mask layer to form sacrificial mask patterns, providing an inhibitor on the surface of the sacrificial mask patterns and the exposed surface of the etching target layer, forming a hard mask pattern between the sacrificial mask patterns using an area selective deposition (ASD) process, and removing the sacrificial mask patterns.

According to an aspect of the disclosure, there is provided a method for manufacturing a semiconductor device that includes forming sacrificial mask patterns on an etching target layer, the sacrificial mask patterns containing a first element, wherein a concentration of the first element in the sacrificial mask patterns decreases progressively as the sacrificial mask patterns extend upward, away from the etching target layer, forming a hard mask pattern by selectively depositing hard mask material between the sacrificial mask patterns, and removing the sacrificial mask patterns, wherein a thickness of the edge portion of the hard mask pattern in contact with the sacrificial mask pattern is greater than a thickness of the central portion of the hard mask pattern.

The specific details of other embodiments are included in the detailed description and drawings.

### BRIEF DESCRIPTION OF DRAWINGS

The above and other aspects and features of the present disclosure will become more apparent by describing in detail embodiments thereof with reference to the attached drawings, in which:

FIG. 1 is a flowchart illustrating a method for manufacturing a semiconductor device according to some embodiments;

FIG. 2 is a diagram for illustrating a method for manufacturing a semiconductor device according to some embodiments;

FIG. 3 is a diagram for illustrating a method for manufacturing a semiconductor device according to some embodiments;

FIG. 4 is a diagram for illustrating a method for manufacturing a semiconductor device according to some embodiments;

FIG. 5 is a diagram for illustrating a method for manufacturing a semiconductor device according to some embodiments;

FIG. 6 is a diagram for illustrating a method for manufacturing a semiconductor device according to some embodiments;

FIG. 7 is a table for illustrating examples of a material and a method used in a method for manufacturing a semiconductor device according to some embodiments;

FIG. 8 is a diagram for illustrating a method for manufacturing a semiconductor device according to some embodiments;

FIG. 9 is a diagram for illustrating a method for manufacturing a semiconductor device according to some embodiments;

FIG. 10 is a diagram for illustrating a method for manufacturing a semiconductor device according to some embodiments;

FIG. 11 is a diagram for illustrating a method for manufacturing a semiconductor device according to some embodiments;

FIG. 12 is a diagram for illustrating a method for manufacturing a semiconductor device according to some embodiments; and

FIG. 13 is a diagram for illustrating a method for manufacturing a semiconductor device according to some embodiments.

### DETAILED DESCRIPTIONS

Hereinafter, embodiments of the present disclosure will be described in detail with reference to the accompanying drawings. The same reference numerals are used for the same components in the drawings, and redundant descriptions thereof will be omitted.

Although terms such as first, second, upper, and lower are used herein to describe various elements or components, these elements or components are not limited by the terms. Rather, the terms are merely used herein to distinguish one element or component from another element or component. Therefore, a first element or component as mentioned below may also be described as a second element or component within the technical spirit of the present disclosure. Further, lower element or component as mentioned below may also be described as an upper element or component within the technical spirit of the present disclosure.

Throughout the specification, when a component is described as “including” a particular element or group of elements, it is to be understood that the component is formed of only the element or the group of elements, or the element or group of elements may be combined with additional elements to form the component, unless the context indicates otherwise.

The term “contact,” “contacting,” “contacts,” or “in contact with,” as used herein, refers to a direct connection (i.e., touching at the point of contact) unless the context clearly indicates otherwise.

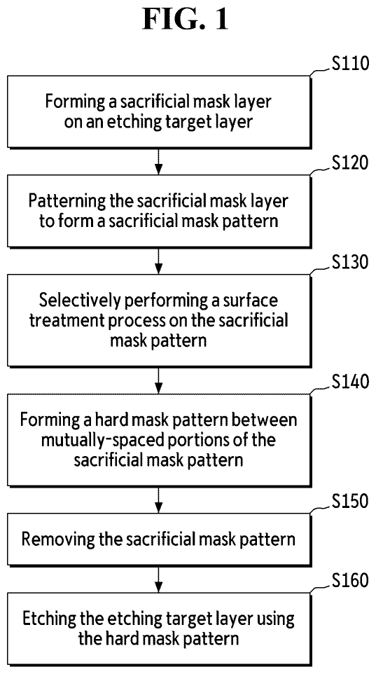

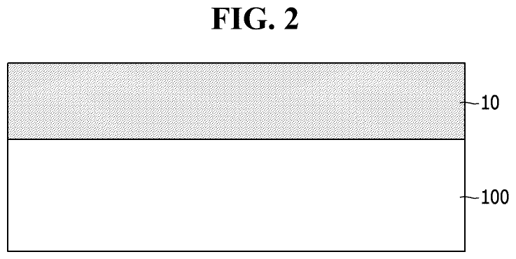

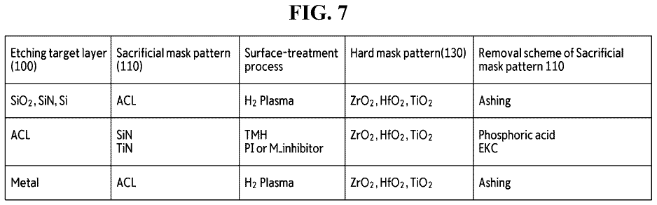

FIG. 1 is a flowchart illustrating a method for manufacturing a semiconductor device according to some embodiments. FIGS. 2 to 6 are diagrams for illustrating a method for manufacturing a semiconductor device according to some embodiments. FIG. 7 is a table for illustrating examples of a material and a method used in a method for manufacturing a semiconductor device according to some embodiments.

Referring to FIGS. 1 and 2, a sacrificial mask layer 10 is formed on an etching target layer 100 in S110.

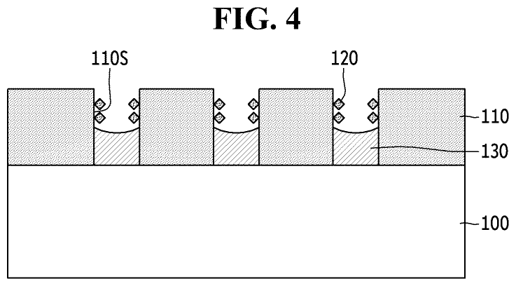

The etching target layer 100 may be a target film subjected to an etching process which is performed by defining an etching region using a hard mask pattern 130 (see FIG. 4). The etching target layer 100 may include a substrate, one or more insulating layers, a dielectric layer, a conductive layer, or a combination thereof. The substrate may be a silicon substrate or a silicon-on-insulator (SOI) substrate. Alternatively, the substrate may include silicon germanium, silicon germanium on insulator (SGOI), indium antimonide, lead telluride compound, indium arsenide, indium phosphide, gallium arsenide, or gallium antimonide.

The sacrificial mask layer 10 may be formed of a material having a higher etch selectivity than that of the etching target layer 100. The sacrificial mask layer 10 may be formed of a material that is easily patterned and removed.

In some embodiments, the sacrificial mask layer 10 may exhibit a gradient in material properties along its thickness. More specifically, the sacrificial mask layer 10 may become hydrophobic (i.e., water repelling or lacking affinity for water) in relation to the vertical distance from the etching target layer 100 toward the upper surface of the sacrificial mask layer 10. Accordingly, as the sacrificial mask layer 10 extends upward from the etching target layer 100, the upper portion of sacrificial mask layer 10 may become hydrophobic while the lower portion may become hydrophilic (i.e., water-attracting or having an affinity for water) due to the gradient in material properties.

For example, the sacrificial mask layer 10 may contain a specific element, and may have a concentration gradient in which the concentration of the specific element decreases as the sacrificial mask layer 10 extends upward, away from the etching target layer 100. The concentration of the specific element in the sacrificial mask layer 10 may be the lowest at the uppermost surface of the sacrificial mask layer 10 and the highest at the lowermost surface of the sacrificial mask layer 10. The specific element may be oxygen or carbon. Because the specific element influences the hydrophilicity of the sacrificial mask layer 10, the hydrophobicity of the sacrificial mask layer 10 may become stronger as the sacrificial mask layer 10 extends from the bottom of the sacrificial mask layer 10 to the top of the sacrificial mask layer 10. An upper portion of the sacrificial mask layer 10 may be hydrophobic, and a lower portion of the sacrificial mask layer 10 may be hydrophilic.

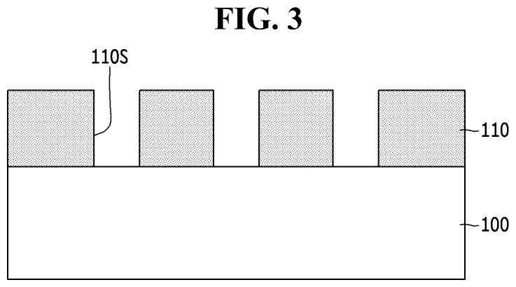

Referring to FIGS. 1 and 3, the sacrificial mask layer 10 is patterned to form sacrificial mask patterns 110 by removing a portion of the sacrificial mask layer 10 in S120 through a photolithography process. Because the removed portion of the sacrificial mask layer 10 may no longer cover the top surface of the etching target layer 100, corresponding portions of the top surface of the etching target layer 100 may be exposed.

The number, size, and arrangement of the sacrificial mask patterns 110 may vary according to a hard mask pattern (130 in FIG. 4) to be formed.

Hereinafter, an upper surface, a lower surface, an upper portion, a lower portion, and the like are defined based on a direction from the etching target layer 100 toward the sacrificial mask pattern 110.

In some embodiments, due to the concentration gradient of the specific element in the sacrificial mask layer 10, an inhibition ratio of deposition of hard mask material to form the hard mask pattern 130 may be relatively greater on the top surface of the sacrificial mask patterns 110 than on the exposed top surface of the etching target layer 100, and the inhibition ratio may increase as the sidewall extends upward, away from the etching target layer 100 (i.e., as the sidewall extends from the lower surface of the sacrificial mask patterns 110 to the upper surface of the sacrificial mask pattern 110). The inhibition ratio may indicate a degree to which formation of the hard mask pattern 130 is suppressed on the sidewall of the sacrificial mask patterns 110.

For example, a growth area in which the hard mask pattern 130 is formed thicker may have hydrophilicity due to the increased concentration of the specific element, and a non-growth area in which the hard mask pattern 130 is formed thinner may have hydrophobicity due to the decreased concentration of the specific element. Accordingly, selective deposition of the hard mask pattern 130 may be selectively performed in the hydrophilic growth area. The hydrophobicity of the sacrificial mask pattern 110 may become stronger as the sacrificial mask layer 10 extends upward, away from the etching target layer 100 (i.e., extends from a lower surface of the sacrificial mask pattern 110 to an upper surface of the sacrificial mask pattern 110). Accordingly, the inhibition ratio of deposition of the hard mask pattern 130 on the sidewall 110S of the sacrificial mask pattern 110 may increase as the sidewall extends upward, away from the etching target layer 100 (i.e., extends from the lower surface of the sacrificial mask pattern 110 to the upper surface of the sacrificial mask pattern 110).

Referring to FIGS. 1 and 4, a surface treatment process for selectively suppressing the formation of the hard mask pattern 130 on the surface of the sacrificial mask patterns 110 may be performed in S130.

The surface treatment process may include, for example, a pretreatment process such as hydrogen plasma and/or a process of providing an inhibitor 120 to the sacrificial mask pattern 110. In some embodiments, the inhibitor 120 may not be provided to the sacrificial mask pattern 110 during the surface treatment process, and the inhibitor 120 may not be formed, unlike the illustrated case.

The pretreatment process may be a hydrophobic treatment process to maintain the hydrophobicity in the non-growth area. Accordingly, an upper portion of the sidewall 110S of the sacrificial mask pattern 110 may remain hydrophobic.

The inhibitor 120 may be selectively adsorbed to a surface having hydrophobicity. Accordingly, as the sidewall 110S of the sacrificial mask pattern 110 extends upward, away from the etching target layer 100, the concentration of the inhibitor 120 on the sidewall 110S of the sacrificial mask pattern 110 may increase. The inhibitor 120 may not be provided on an exposed surface of the etching target layer 100 not covered with the sacrificial mask pattern 110.

Accordingly, as the sidewall 110S of the sacrificial mask pattern 110 extends away from the etching target layer 100, (i.e., extends from the lower surface to the upper surface of the sacrificial mask pattern 110,) the inhibition ratio, indicating a degree to which the formation of the hard mask pattern 130 is suppressed on the sidewall 110S of the sacrificial mask pattern 110, may increase.

Subsequently, the hard mask pattern 130 may be formed between the sacrificial mask patterns 110 in S140.

The hard mask pattern 130 is formed by an area selective deposition (ASD) process. The hard mask pattern 130 may be selectively formed on the growth area which is hydrophilic. The hard mask pattern 130 may be selectively formed on a hydrophilic portion of the sidewall 110S of the sacrificial mask pattern 110 and the upper surface of the etching target layer 100.

A thickness of the hard mask pattern 130 on the etching target layer 100 may decrease as the hard mask pattern 130 extends away from the sidewalls of the sacrificial mask pattern 110. When cross-sectional thickness of the hard mask pattern 130 is measured along a horizontal direction of the hard mask pattern 130, a thickness of an edge portion of the hard mask pattern 130 in contact with the sidewall of the sacrificial mask pattern 110 may be greater than a thickness of a central portion of the hard mask pattern 130. Accordingly, an upper surface of the hard mask pattern 130 may have a “U” or “V” shape. This may be caused by a process of forming the hard mask pattern 130 using the sacrificial mask pattern 110 in which the inhibition ratio of deposition of the hard mask pattern 130 on the sidewall 110S increases as the sidewall 110S extends toward the upper surface of the sacrificial mask pattern 110.

For example, the hard mask pattern 130 may include a ternary or quaternary oxide including a metal element. The metal element may include at least one of zirconium (Zr), hafnium (Hf), titanium (Ti), and yttrium (Y).

For example, the sacrificial mask pattern 110 may include an amorphous carbon layer (ACL).

Referring to FIGS. 1, 4, and 5, the sacrificial mask pattern 110 may be removed in S150. Accordingly, the hard mask pattern 130 may be formed into a protruding shape on the etching target layer 100.

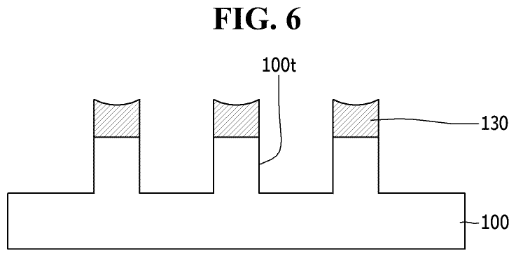

Referring to FIGS. 1 and 6, the etching target layer 100 may be etched using the hard mask pattern 130 in S160. Accordingly, a trench 100t may be formed in the etching target layer 100. Thereafter, a subsequent process may be performed to manufacture a semiconductor device.

FIG. 7 is a table for illustrating examples of materials and a method used in a method for manufacturing a semiconductor device according to some embodiments.

Referring to FIGS. 1 to 7, when the etching target layer 100 includes silicon oxide (SiO₂), silicon nitride (SiN), or silicon (Si), the sacrificial mask pattern 110 may include an amorphous carbon layer (ACL), the surface treatment process may include a hydrogen plasma process, the hard mask pattern 130 may include at least one of zirconium dioxide (ZrO₂), hafnium dioxide (HfO₂), and titanium dioxide (TiO₂), and the sacrificial mask pattern 110 may be removed in an ashing process. The etching target layer 100 may be a silicon substrate or a substrate containing oxide.

When the etching target layer 100 includes ACL, the sacrificial mask pattern 110 may include silicon nitride (SiN) or titanium nitride (TiN), the surface treatment process may include a process of providing the inhibitor 120, the inhibitor 120 may include trimethylhydrazine (TMH), polyimide or a metal element constituting the hard mask, the hard mask pattern 130 may include at least one of zirconium dioxide (ZrO₂), hafnium dioxide (HfO₂), and titanium dioxide (TiO₂), and the sacrificial mask pattern 110 may be removed using a cleaning solution including phosphoric acid or an Eastman Kodak Company (EKC) solution.

When the etching target layer 100 includes a metal, the sacrificial mask pattern 110 may include ACL, the surface treatment process may include a hydrogen plasma process, the hard mask pattern 130 may include at least one of zirconium dioxide (ZrO₂), hafnium dioxide (HfO₂), and titanium dioxide (TiO₂), and the sacrificial mask pattern 110 may be removed in an ashing process.

As the aspect ratio of etching patterns for manufacturing the semiconductor device increases, the thickness of the hard mask pattern may also increase. As a result, the hard mask pattern may be subjected to warpage, and quality of the hard mask pattern may be deteriorated due to line edge roughness (LER) and line width roughness (LWR). In addition, warpage of a wafer may become worse in a process of manufacturing a semiconductor device as the thickness of the hard mask pattern increases. Accordingly, a process for providing a hard mask having a relatively smaller thickness and having a high etch selectivity, along with a process for performing etching of the hard mask to form the hard mask pattern, becomes important.

However, in an etching process for manufacturing a semiconductor device according to some embodiments, the sacrificial mask pattern 110 is formed by patterning the sacrificial mask layer 10 made of a material that is easily patterned and removed, and then the hard mask pattern 130 is formed between the sacrificial mask patterns 110 using the ASD process. Because the hard mask pattern 130 itself is not patterned through an etching process, the hard mask material needs not necessarily have the high etch selectivity, and thus high selectivity etching process for etching the hard mask material to form the hard mask pattern may not be necessary. In addition, quality degradation of the hard mask pattern 130 due to LER and LWR which is caused from the thickness of the hard mask pattern may be alleviated, and warpage of a wafer may be reduced in a process of manufacturing a semiconductor device. Since the sacrificial mask pattern 110 is formed by patterning the sacrificial mask layer 10 made of a material that is easy to be patterned and removed, the process for forming the hard mask pattern 130 may become simpler.

In addition, because the hard mask pattern 130 is formed between the sacrificial mask patterns 110, when the hard mask pattern 130 is formed using the ASD process, the hard mask pattern 130 may not be overgrown on the side surface of the sacrificial mask patterns 110.

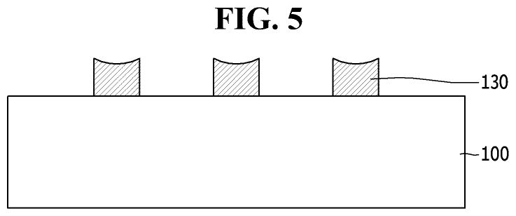

In the case of an etching process using the hard mask pattern having the high aspect ratio, etching damage may occur at a corner of the hard mask pattern. However, in the etching process for manufacturing a semiconductor device according to some embodiments, the thickness of the hard mask pattern 130 may be thicker at the edge of the hard mask pattern 130 as illustrated in FIG. 5. Because the thickness of the hard mask pattern 130 may be relatively greater at the corner portion than at the center portion of the hard mask pattern 130, the cross-sectional shape of the hard mask pattern 130 may be a “U” or “V” shape. Thus, etching damage at the corner portion of the hard mask pattern 130 may be reduced.

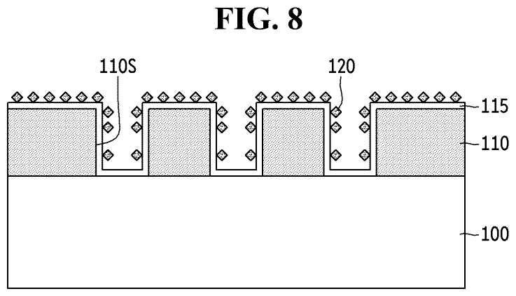

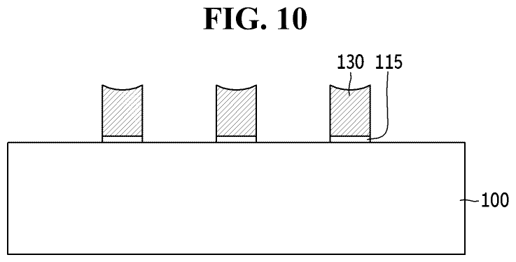

FIGS. 8 to 10 are diagrams for illustrating a method for manufacturing a semiconductor device according to some embodiments. FIG. 8 illustrates a distribution of inhibitors adsorbing on the hard mask pattern 130 and the top surface of the etching target layer 100 after the process described with reference to FIG. 3. For convenience of description, differences from those as described above with reference to FIGS. 1 to 7 will be described.

Referring to FIGS. 1 and 8, in the method for manufacturing a semiconductor device according to some embodiments, unlike the above-described method, the sacrificial mask pattern 110 and the sacrificial mask layer 10 of FIG. 2, may not contain the specific element. Alternatively, the sacrificial mask pattern 110 and the sacrificial mask layer 10 of FIG. 2, may contain the specific element with a constant concentration gradient of the specific element within the sacrificial mask layer 10 regardless of the vertical distance from the etching target layer 100.

In some embodiments, performing a surface treatment process of selectively suppressing the formation of the hard mask pattern 130 on the surface of the sacrificial mask pattern 110 in S130 may include forming an oxide layer 115 on the sacrificial mask pattern 110 and on the exposed surface of the etching target layer 100, and providing the inhibitor 120 on the oxide layer 115.

The oxide layer 115 may be formed along the sacrificial mask pattern 110 and the exposed surface of the etching target layer 100. The oxide layer 115 may be formed conformally along a profile of the sacrificial mask pattern 110 and the exposed regions of the etching target layer 100 not covered with the sacrificial mask pattern 110. The oxide layer 115 may be formed by, for example, an atomic layer deposition (ALD) process. The oxide layer 115 may have a thickness of, for example, several nanometers.

Subsequently, the inhibitor 120 may be provided on the oxide layer 115. When the sacrificial mask pattern 110 exhibits a high aspect ratio, the inhibitor 120 may be less effectively transferred to the lower portion of the sidewall 110S of the sacrificial mask pattern 110 than to the upper portion of the sidewall 110S of the sacrificial mask pattern 110. Therefore, the concentration of the inhibitor 120 on the sidewall 110S of the sacrificial mask pattern 110 may increase as the sidewall extends upward, away from the etching target layer 100 (from the lower surface of the sacrificial mask pattern 110 to the upper surface of the sacrificial mask pattern 110). Likewise, the inhibitor 120 may be less effectively transferred to the exposed surface of the etching target layer 100 not covered with the sacrificial mask pattern 110. Accordingly, the inhibition ratio of deposition of the hard mask pattern 130 on the sidewall 110S of the sacrificial mask pattern 110 may increase as the sidewall extends upward, away from the etching target layer 100 (from the lower surface to the upper surface of the sacrificial mask pattern 110). Likewise, the inhibition ratio of deposition of the hard mask pattern 130 on the exposed surface of the etching target layer 100 may become low.

The inhibitor 120 may be, for example, an organometallic inhibitor which includes a metal material constituting the hard mask pattern 130, and which does not react with a reactant for depositing the hard mask pattern 130, and includes a C-ring ligand and an alkoxy ligand. The C-ring ligand may be a molecule or an ion having a carbon ring structure capable of binding to a metal ion. The inhibitor 120 may include, for example, a metal and a precursor as a compound of Chemical Formula R¹ₙ(OR²)ₚ(O(O)CR⁴)₃₋ₙ₋ₚSi—R⁷—SiR³ₘ(O(O)CR⁵)_{q}(OR⁶)_{3-m-q}, wherein each of R¹ and R³ independently represents H or C₁ to C₄ linear or branched, saturated, monounsaturated or polyunsaturated, cyclic, entirely or partially-fluorinated hydrocarbon, each of R², R⁶ and R⁷ independently represents C1 to C6 linear or branched, saturated, monounsaturated or polyunsaturated, cyclic, aromatic, entirely or partially-fluorinated hydrocarbon, each of R⁴ and R⁵ independently represents H, C₁ to C₆ linear or branched, saturated, monounsaturated or polyunsaturated, cyclic, aromatic, entirely or partially-fluorinated hydrocarbon, n is 0 to 3, m is 0 to 3, q is 0 to 3, p is 0 to 3, wherein n+m≥1, n+p≤3 and m+q≤3.

The concentration of the inhibitor 120 on the sidewall 110S of the sacrificial mask pattern 110 may be adjusted by controlling the time duration of the inhibitor 120 exposure.

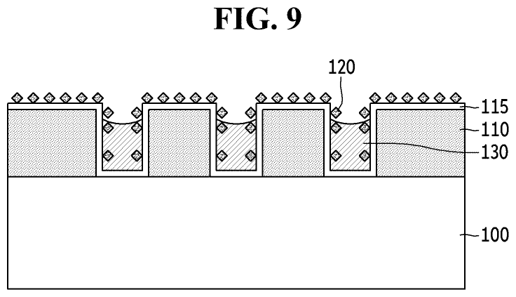

Referring to FIGS. 1 and 9, the hard mask pattern 130 may be formed by filling spaces between the sacrificial mask patterns 110 with hard mask material in S140. The hard mask pattern 130 may be formed on the oxide layer 115.

Referring to FIGS. 1, 9, and 10, the sacrificial mask pattern 110 may be removed in S150. While removing the sacrificial mask pattern 110, the oxide layer 115 formed on the upper surface of the sacrificial mask pattern 110 and the sidewall 110S thereof may also be removed. The oxide layer 115 under the hard mask pattern 130 may remain. Accordingly, the hard mask pattern 130 for etching the etching target layer 100 may be formed.

Subsequently, the etching target layer 100 may be etched using the hard mask pattern 130 in S160. Accordingly, a trench (e.g., 100t of FIG. 6) may be formed in the etching target layer 100. Thereafter, a subsequent process may be performed to manufacture a semiconductor device.

For example, when the aspect ratio of the sacrificial mask pattern 110 is low, the hard mask pattern 130 may be formed by the method for manufacturing the semiconductor device described with reference to FIGS. 1 to 7. When the aspect ratio of the sacrificial mask pattern 110 is high, the hard mask pattern 130 may be formed by the method for manufacturing the semiconductor device described with reference to FIGS. 8 to 10.

In the method for manufacturing a semiconductor device according to some embodiments, the oxide layer 115 may be omitted. For example, performing a surface treatment process of selectively suppressing the formation of the hard mask pattern 130 on the surface of the sacrificial mask pattern 110 in S130 may include providing the inhibitor 120 on the hard mask pattern 130 and on the exposed surface of the etching target layer 100.

The inhibitor 120 may be less effectively transferred to the lower portion of the sacrificial mask pattern 110 than to the upper portion of the sacrificial mask pattern 110 due to the high aspect ratio of the sacrificial mask pattern 110. The concentration of the inhibitor 120 on the sidewall 110S of the sacrificial mask pattern 110 may increase as the sidewall extends upward, away from the etching target layer 100 (from the bottom to the top of the sacrificial mask pattern 110).

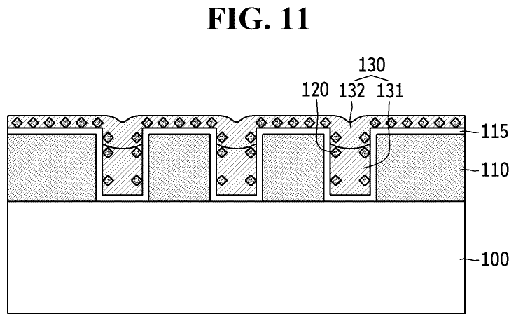

FIGS. 11 to 13 are diagrams for illustrating a method for manufacturing a semiconductor device according to some embodiments. For reference, FIG. 11 illustrates a distribution of inhibitors adsorbing on the hard mask pattern 130 and the top surface of the etching target layer 100 after the process described with reference to FIG. 9 being performed. For convenience of description, differences from those described above with reference to FIGS. 1 to 10 will be described.

Referring to FIGS. 1, 11, and 12, in the method for manufacturing a semiconductor device according to some embodiments, the forming of the hard mask pattern 130 between the sacrificial mask patterns 110 in S140 may include forming a first hard mask pattern 131, forming a second hard mask pattern 132, and performing a planarization process on the second hard mask pattern 132.

For example, when the aspect ratio of the sacrificial mask pattern 110 is high, the hard mask pattern 130 may be formed by a process of forming the first hard mask pattern 131 and the second hard mask pattern 132.

Specifically, referring to FIG. 11, the first hard mask pattern 131 may be formed on the oxide layer 115 and between the sacrificial mask patterns 110.

Subsequently, the second hard mask pattern 132 may be formed to cover the first hard mask pattern 131 and the sacrificial mask pattern 110. The second hard mask pattern 132 may cover the oxide layer 115. Accordingly, the hard mask pattern 130 including the first hard mask pattern 131 and the second hard mask pattern 132 may be formed.

The second hard mask pattern 132 and the first hard mask pattern 131 may include the same material. The second hard mask pattern 132 and the first hard mask pattern 131 may or may not be distinguished from each other.

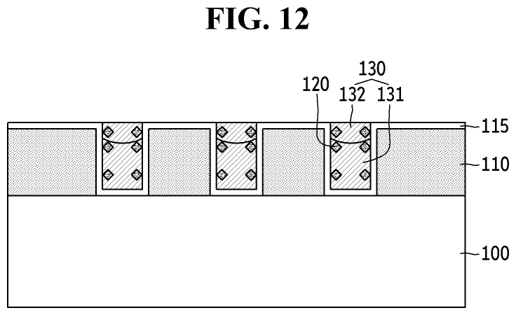

Subsequently, referring to FIG. 12, an etching process may be performed on the second hard mask pattern 132. For example, a planarization process such as a chemical mechanical polishing (CMP) process or an etch back process may be performed on the second hard mask pattern 132.

Alternatively, the planarization process may be performed to expose the sacrificial mask pattern 110. The upper surface of the sacrificial mask pattern 110 and the upper surface of the hard mask pattern 130 may be coplanar with each other.

In some embodiments, the top surface of the hard mask pattern 130 may be flat.

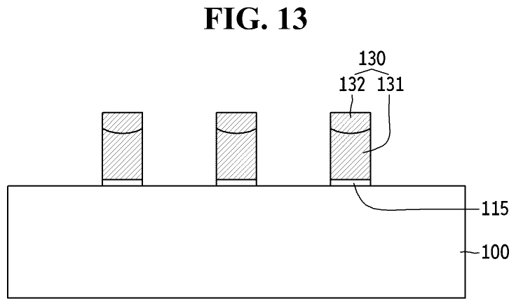

Subsequently, referring to FIG. 13, the sacrificial mask pattern 110 may be removed. Accordingly, the hard mask pattern 130 for etching the etching target layer 100 may be formed.

Subsequently, the etching target layer 100 may be etched using the hard mask pattern 130 in S160. Accordingly, the trench (e.g., 100t of FIG. 6) may be formed in the etching target layer 100. Thereafter, a subsequent process may be performed to manufacture a semiconductor device.

Although embodiments of the present disclosure have been described with reference to the accompanying drawings, the present disclosure is not limited to the above embodiments, but may be implemented in various different forms. A person skilled in the art may appreciate that the present disclosure may be practiced in other forms without changing the technical spirit or essential characteristics of the present disclosure. Therefore, it should be appreciated that the embodiments described above are not restrictive but illustrative in all respects.

What is claimed is:

1. A method for manufacturing a semiconductor device, the method comprising:
forming a sacrificial mask layer on an etching target layer;
patterning the sacrificial mask layer to form sacrificial mask patterns;
forming a hard mask pattern by selectively depositing hard mask material between the sacrificial mask patterns; and
removing the sacrificial mask patterns,
wherein an inhibition ratio, indicating a degree to which formation of the hard mask pattern is suppressed on a sidewall of the sacrificial mask patterns, increases as the sidewall extends upward, away from the etching target layer.

2. The method of claim 1, wherein the sacrificial mask layer is formed to contain a first element, wherein a concentration of the first element within the sacrificial mask patterns decreases progressively as the sacrificial mask layer extends upward, away from the etching target layer.

3. The method of claim 2, wherein the first element is oxygen or carbon.

4. The method of claim 2, wherein, due to a gradient in the concentration of the first element within the sacrificial mask layer, hydrophobicity of the sacrificial mask layer increases with vertical distance from the etching target layer, thereby rendering an upper sidewall of the sacrificial mask layer hydrophobic and a lower sidewall of the sacrificial mask layer hydrophilic.

5. The method of claim 4, wherein the selective deposition of the hard mask material is performed by selectively depositing the hard mask material on the lower sidewall of the sacrificial mask layer which is hydrophilic and inhibiting depositing the hard mask material on the upper sidewall of the sacrificial mask layer which is hydrophobic.

6. The method of claim 1, further comprising:
performing a surface treatment process on a surface of the sacrificial mask patterns for suppressing the formation of the hard mask pattern.

7. The method of claim 1, wherein the hard mask pattern contains at least one of Zr, Hf, Ti, and Y, and the sacrificial mask patterns includes an amorphous carbon layer (ACL).

8. The method of claim 1, wherein a thickness of the hard mask pattern near the sacrificial mask patterns is greater than a thickness of the hard mask pattern at central portion of the hard mask pattern.

9. The method of claim 1, wherein the forming of the hard mask pattern includes:
forming a first hard mask pattern by selectively depositing first hard mask material between the sacrificial mask patterns;
forming a second hard mask pattern covering the first hard mask pattern and the sacrificial mask patterns; and
performing a planarization process on the second hard mask pattern to form the hard mask pattern.

10. The method of claim 1, further comprising:
performing etching process on the etching target layer using the hard mask pattern.

11. A method for manufacturing a semiconductor device, the method comprising:
forming a sacrificial mask layer on an etching target layer;
patterning the sacrificial mask layer to form sacrificial mask patterns;
providing an inhibitor on a surface of the sacrificial mask patterns and an exposed surface of the etching target layer;
forming a hard mask pattern between the sacrificial mask patterns using an area selective deposition (ASD) process; and
removing the sacrificial mask patterns.

12. The method of claim 11, wherein the inhibitor includes an organic metal and a C-ring ligand which inhibit forming of the hard mask patterns.

13. The method of claim 12, wherein the organic metal does not react with a reactant included in hard mask material, and is subsequently incorporated into the hard mask pattern.

14. The method of claim 13, wherein a concentration of the inhibitor on sidewalls of the sacrificial mask patterns increases as the sidewall extends upward, away from the etching target layer.

15. The method of claim 14, further comprising:
before providing the inhibitor on the surfaces of the sacrificial mask patterns, forming an oxide layer on the sacrificial mask patterns and the exposed surface of the etching target layer.

16. The method of claim 11, wherein a thickness of an edge portion of the hard mask pattern in contact with the sacrificial mask patterns is greater than a thickness of a central portion of the hard mask pattern.

17. The method of claim 11, further comprising:
performing an etching process on the etching target layer using the hard mask pattern.

18. A method for manufacturing a semiconductor device, the method comprising:
forming sacrificial mask patterns on an etching target layer, the sacrificial mask patterns containing a first element, wherein a concentration of the first element in the sacrificial mask patterns decreases progressively as the sacrificial mask patterns extend upward, away from the etching target layer;
forming a hard mask pattern by selectively depositing hard mask material between the sacrificial mask patterns; and
removing the sacrificial mask patterns,
wherein a thickness of an edge portion of the hard mask pattern in contact with the sacrificial mask pattern is greater than a thickness of the central portion of the hard mask pattern.

19. The method of claim 18, further comprising:
providing an inhibitor on surfaces of the sacrificial mask patterns.

20. The method of claim 19, wherein a concentration of the inhibitor on a sidewall of the sacrificial mask patterns increases as the sidewall extends upward, away from the etching target layer.
